(19) United States
(12) Patent Application Publication
(10) Pub. No.: US 2013/0161274 A1
(43) Pub. Date: Jun. 27, 2013

(54) MOUNTING APPARATUS FOR MOUNTING TRAY FOR SECURING EXPANSION CARD

(71) Applicant: WEN-HU LU, Shenzhen City (CN)

(72) Inventor: WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/611,102

(22) Filed: Sep. 12, 2012

(30) Foreign Application Priority Data
Dec. 26, 2011 (CN) 201110440991.1

(51) Int. Cl. H05K 7/14; H05K 7/18

(52) U.S. Cl. 211/41.17

(57) ABSTRACT

A mounting apparatus includes a chassis, a mounting tray, and a securing device. The chassis includes a positioning hole. The securing device includes a securing member attached to the mounting tray, a rotating shaft received in the securing member, a driving member attached to the rotating shaft, and a resilient member located between the driving member and the securing member. The rotating shaft includes an engaging portion. The driving member rotates the rotating shaft relative to the securing member between the unlocked and locked positions; when the rotating shaft is in the unlocked position, the engaging portion is aligned with the positioning hole and arranged in a first direction, and when the rotating shaft is in the locked position, the resilient member is deformed, and the engaging portion is engaged in the positioning hole and arranged in a second direction substantially perpendicular to the first direction.

### BACKGROUND

1. Technical Field

The present disclosure relates to mounting apparatuses, more particularly to a mounting apparatus for a mounting tray, the mounting tray being configured for securing an expansion card.

2. Description of Related Art

A computer system includes expansion cards, such as sound cards, video cards, and graphics cards, for enhancing the capabilities of the computer system. The expansion cards are often mounted to a mounting tray, and the mounting tray is secured to a computer casing of the computer system with screws. However, using screws to attach the mounting tray is laborious and time consuming. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus in accordance with an embodiment.

FIG. 2 is an exploded, isometric view of a securing device of the mounting apparatus of FIG. 1.

FIG. 3 is an enlarged view of the circled portion III of FIG. 1.

FIG. 4 is an assembled view of the mounting apparatus of FIG. 1.

FIG. 5 is a cross-sectional view of FIG. 4, taken along a line V-V, and the securing device is located in a lock position.

FIG. 6 is similar to FIG. 5, but the securing device is located in an unlock position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

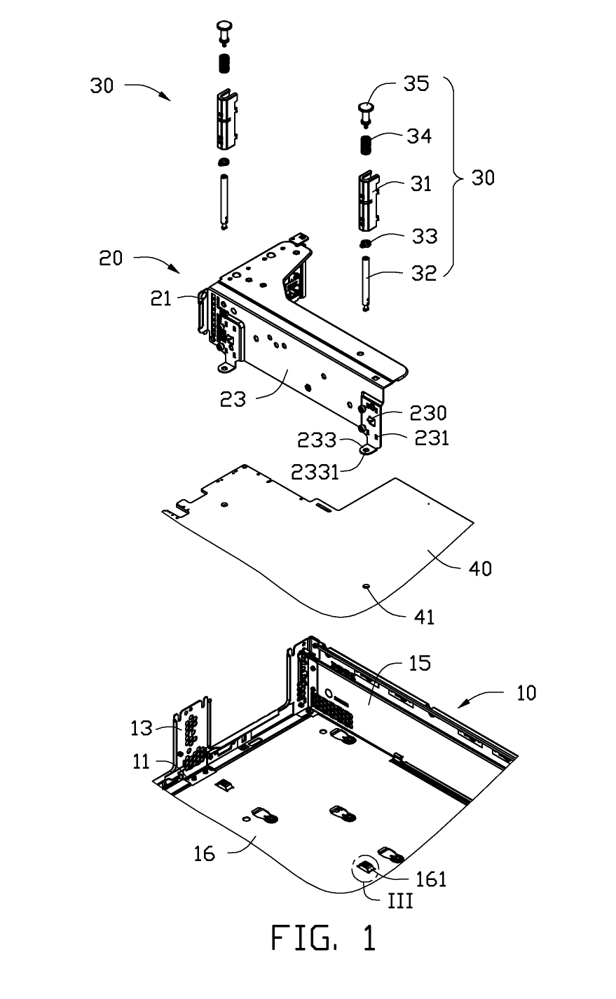

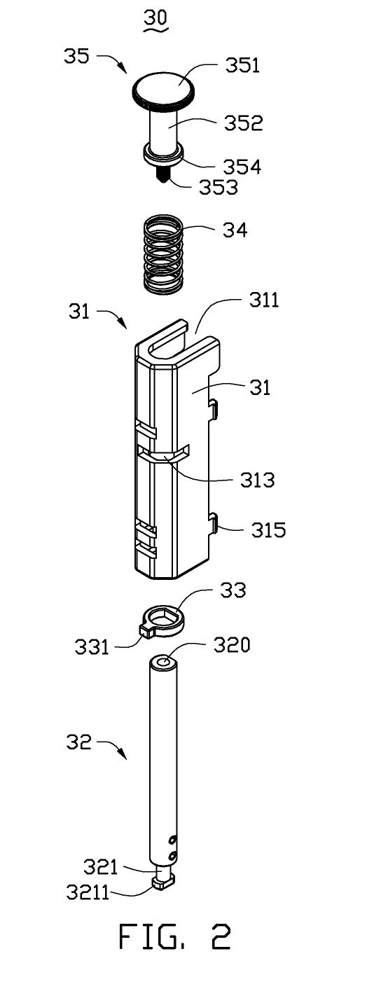

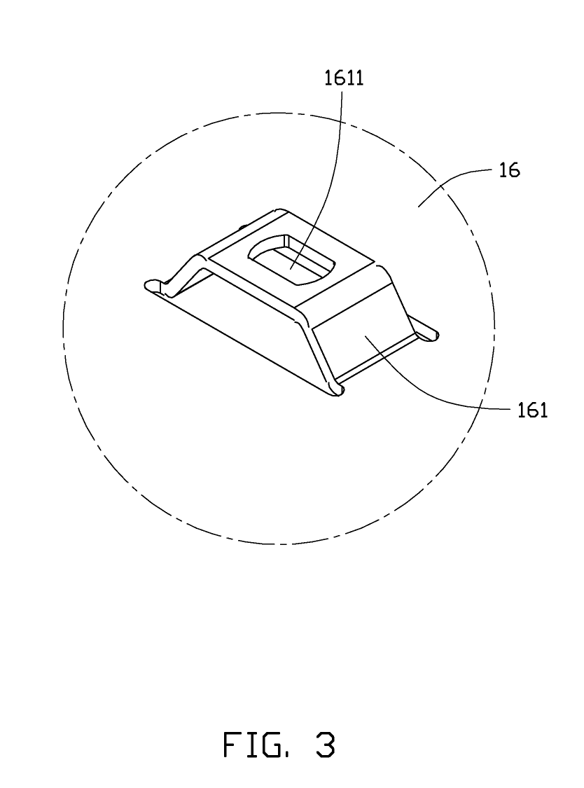

FIGS. 1-3 illustrate a mounting apparatus in accordance with an embodiment. The mounting apparatus comprises a chassis 10, a mounting tray 20, and two securing devices 30.

The chassis 10 comprises a bottom plate 11, a front plate 13 extending from a first edge of the bottom plate 11, and a side plate 15 extending from a second edge of the bottom plate 11.

A supporting plate 16 is secured to the bottom plate 11, and a circuit board 40 can be secured to the supporting plate 16. Two positioning portions 161 protrude from the supporting plate 16, and each of the two positioning portions 161 defines a positioning hole 1611. The positioning hole 1611 is substantially rectangular, and comprises two opposite long edges and two opposite short edges. In one embodiment, the positioning hole 1611 is an oval.

The mounting tray 20 is used to receiving a plurality of expansion cards (not shown), and comprises a front panel 21 and a side panel 23 extending from the front panel 21. Two mounting portions 230, each with four clipping holes 231, are secured to the side panel 23. A securing piece 233 extends from each of the two mounting portions 230. The securing piece 233 defines a securing hole 2331. Two through holes 41 are defined in the circuit board 40.

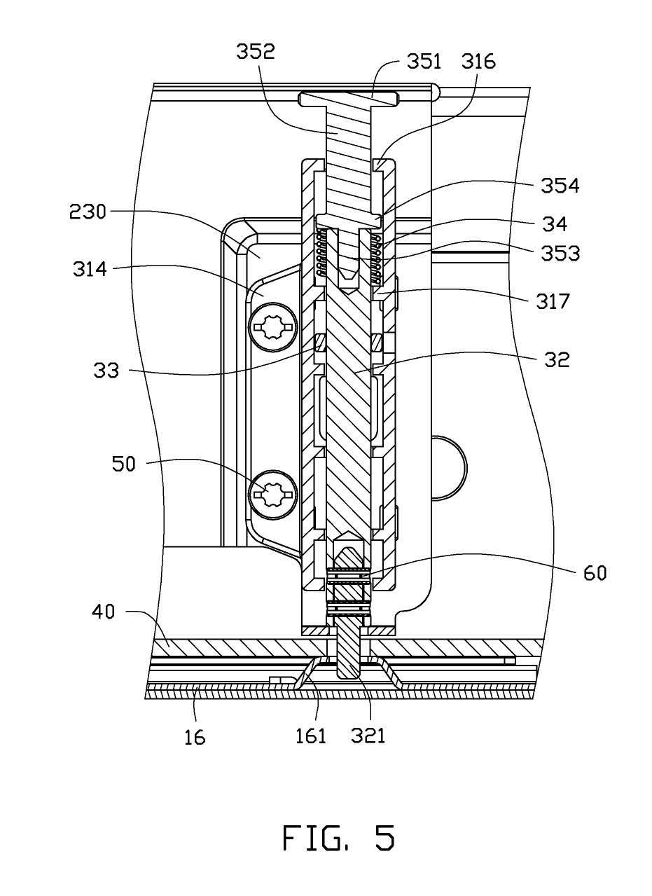

Each of the two securing devices 30 comprises a securing member 31, a rotating shaft 32 received in the securing member 31, an angle indicating member 33 attached to the rotating shaft 32, a resilient member 34 attached to the rotating shaft 32, and a driving member 35. In one embodiment, the resilient member 34 is a compression spring. The securing member 31 defines a receiving slot 311 and a sliding slot 313 communicating with the receiving slot 311. In one embodiment, an extending direction of the receiving slot 311 is substantially perpendicular to the sliding slot 313. A securing panel 314 (see FIG. 5) extends from a side edge of the securing member 31, and four clamping portions 315 extend from the two edges of the securing member 31. In one embodiment, the receiving slot 311 is U-shaped, and the four clamping portions 315 are arranged at an entrance of the receiving slot 311. Two blocking portions 316 (see FIG. 5) and two resisting portions 317 (see FIG. 5) are located on an inner surface of the securing member 31.

An accommodating hole 320 is defined in the rotating shaft 32, and an extending portion 321 extends from a bottom of the rotating shaft 32. In one embodiment, the extending portion 321 can be secured to the rotating shaft 32 by two connecting members 60 (see FIG. 5). An engaging portion 3211 is attached to the extending portion 321 and corresponds to the positioning hole 1611. A cross-section of the engaging portion 3211 is substantially rectangular and comprises two first opposite ends and two second opposite ends. Each of the two first opposite ends is longer than each of the two second opposite ends. When the two first opposite ends are aligned with the two opposite long edges of the positioning hole 1611, the engaging portion 3211 can be inserted into the positioning hole 1611. An angle indicating block 331 is located on the angle indicating member 33.

The driving member 35 comprises a head 351, a first driving portion 352, a second driving portion 353, and an abutting portion 354 connected to the first driving portion 352 and the second driving portion 353. In one embodiment, a diameter of the head 351 is greater than a diameter of the receiving slot 311, and a diameter of the first driving portion 352 is less than the diameter of the receiving slot 311 and greater than a diameter of the second driving portion 353. The abutting portion 354 abuts each of the two blocking portions 316, and a diameter of the abutting portion 354 is less than the diameter of the first driving portion 352 and greater than the diameter of the second driving portion 353.

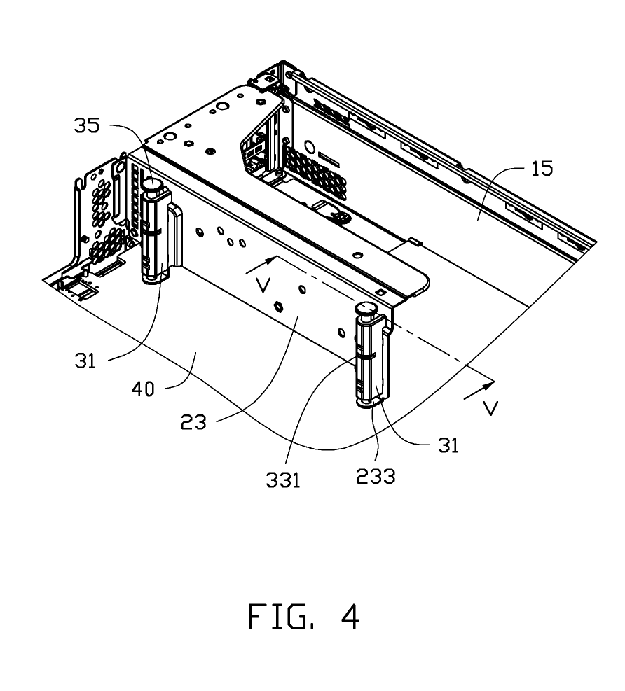

FIGS. 4-6 illustrate an assembled view of the mounting apparatus in accordance with an embodiment. In assembly, the front panel 21 is secured to the front plate 13 by screws. The angle indicating member 33 is secured to the rotating shaft 32. The rotating shaft 32 is received in the receiving slot 311, and the angle indicating block 331 is received in the sliding slot 313. The resilient member 34 is secured to the driving member 35, and the driving member 35 is received in the receiving slot 311 from the entrance of the receiving slot 311. The second driving portion 353 is engaged in the accommodating hole 320, to secure the driving member 35 to the rotating shaft 32.

Each of the two securing devices 30 is attached to each of the two mounting portions 230, and the four clamping portions 315 are engaged in the four clipping holes 231. Two fixing members 50 are used to secure the securing panel 314 to each of the two mounting portions 230. In this way, each of the two securing devices 30 is secured to each of the two the mounting portions 230. The engaging portion 3211 extends through the securing hole 2331, and the resilient member 34 is located between the abutting portion 354 and the two resisting portions 317. The circuit board 40 is secured to the supporting plate 16, and each of the two through holes 41 is aligned with the positioning hole 1611.

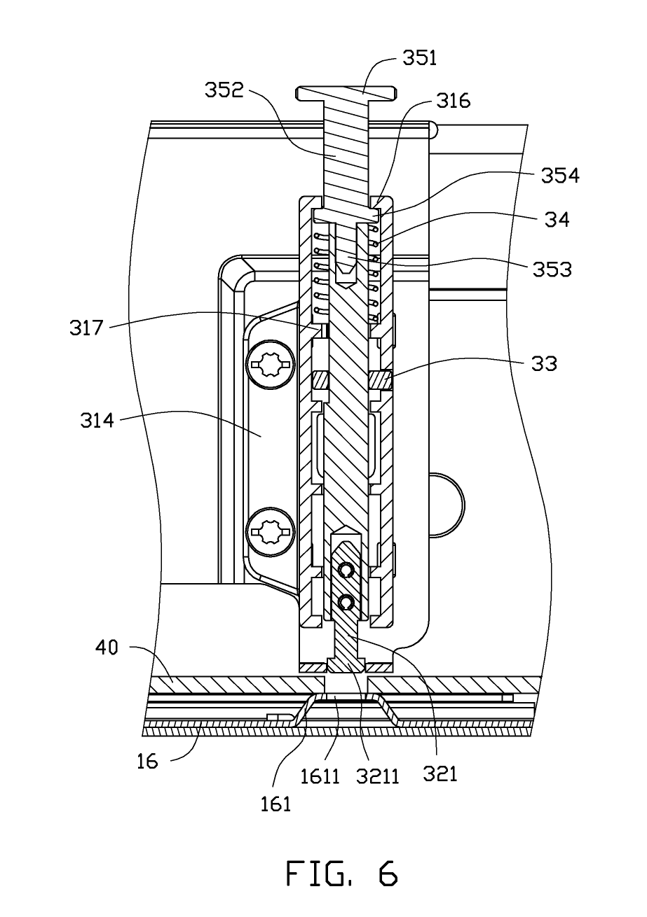

The driving member 35 can rotate the rotating shaft 32 relative to the securing member 31, from an unlocked position (see FIG. 6) to a locked position (see FIG. 5). In the unlocked position, the abutting portion 354 abuts each of the two blocking portions 316, the angle indicating block 331 is positioned in a first end of the sliding slot 313, and the engaging portion 3211 is aligned with the positioning hole 1611 and arranged in a first direction. In the locked position, the resilient member 34 is deformed, the angle indicating block 331 is positioned in a second end of the sliding slot 313, and the engaging portion 3211 is engaged in the positioning hole 1611 and arranged in a second direction substantially perpendicular to the first direction.

When the mounting tray 20 is secured to the circuit board 40, the rotating shaft 32 is located in the locked position. The engaging portion 3211 is aligned with each oft he the two through holes 41. The two first opposite ends of the engaging portion 3211 are aligned with the two opposite long edges of the positioning hole 1611, so that the engaging portion 3211 can be inserted into the positioning hole 1611. The driving member 35 is rotated and moved towards the circuit board 40, until the engaging portion 3211 extends through each of the two through holes 41 and the positioning hole 1611. Simultaneously, the resilient member 34 is deformed. The driving member 35 is further rotated clockwise, the engaging portion 3211 is moved in the positioning hole 1611, until the angle indicating block 331 slides to the second end of the sliding slot 313. When the two first opposite ends of the engaging portion 3211 are aligned with the two opposite short edges of the positioning hole 1611, the engaging portion 3211 can be engaged in the positioning hole 1611. In one embodiment, the angle indicating block 331 is used to decide a rotating angle of the rotating shaft 32, and the rotating angular extent of the rotating shaft 32 is 0°-90°. That is, when the driving member 35 is rotated about 90°, the angle indicating block 331 can be slid to the second end of the sliding slot 313 from the first end of the sliding slot 313.

In disassembly, the driving member 35 rotates the rotating shaft 32 relative to the securing member 31, until the two first opposite ends of the engaging portion 3211 are aligned with the two opposite long edges of the positioning hole 1611. The angle indicating block 331 can be slid to the first end of the sliding slot 313 from the second end of the sliding slot 313. The resilient member 34 is released, to move the rotating shaft 32 away from the circuit board 40, until the abutting portion 354 abuts each of the two blocking portions 316. Thereby, the engaging portion 3211 can be disengaged from the positioning hole 1611 and each of the two through holes 41, to disengage the mounting tray 20 from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a chassis defining a positioning hole;
a mounting tray attached to the chassis; and
a securing device comprising a securing member attached to the mounting tray, a rotating shaft received in the securing member, a driving member attached to the rotating shaft, and a resilient member attached to the driving member; the securing member comprises a resisting portion; the rotating shaft comprises an engaging portion, and the driving member comprises an abutting portion;
wherein the resilient member is located between the abutting portion and the resisting portion, the rotating shaft is moveable by the driving member to deform the resilient member so that the engaging portion is engaged in the positioning hole.

2. The mounting apparatus of claim 1, wherein the engaging portion is engaged in the positioning hole in a first direction, and the engaging portion is disengaged from the positioning hole in a second direction that is substantially perpendicular to the first direction.

3. The mounting apparatus of claim 2, wherein the engaging portion comprises two first opposite ends and two second opposite ends, the positioning hole comprises two opposite long edges and two opposite short edges; when the two first opposite ends of the engaging portion are aligned with the two opposite short edges of the positioning hole, the engaging portion is engaged in the positioning hole, and when the two first opposite ends of the engaging portion are aligned with the two opposite long edges of the positioning hole, the engaging portion is disengaged from the positioning hole.

4. The mounting apparatus of claim 3, wherein a cross-section of the engaging portion is substantially a rectangle, the positioning hole is a rectangle, and a length of the engaging portion is substantially equal to a length of the positioning hole and greater than a width of the positioning hole.

5. The mounting apparatus of claim 1, wherein the securing member defines a sliding slot, the securing device further comprises an angle indicating member attached to the rotating shaft, and the angle indicating member comprises an angle indicating block slidably received in the sliding slot.

6. The mounting apparatus of claim 1, wherein the securing member further comprises a blocking portion, and when the engaging portion is disengaged from the positioning hole, the abutting portion abuts the blocking portion.

7. The mounting apparatus of claim 1, wherein the driving member comprises a first driving portion and a second driving portion, and the abutting portion is connected to the first driving portion and the second driving portion.

8. The mounting apparatus of claim 7, wherein the rotating shaft defines an accommodating hole, and the second driving portion is received in the accommodating hole.

9. The mounting apparatus of claim 1, wherein the mounting tray comprises a side panel, the side panel comprises a mounting portion, and a securing panel extends from the securing member and is secured to the mounting portion.

10. The mounting apparatus of claim 9, wherein the securing member defines a receiving slot, the driving member is received in the receiving slot, the mounting portion defines a clipping hole, and a clamping portion extends from an edge of the receiving slot and is engaged in the clipping hole.

11. The mounting apparatus of claim 1, wherein the chassis comprises a bottom plate and a supporting plate, the supporting plate is attached to the bottom plate and configured for securing a circuit board, the positioning hole is defined in the supporting plate, and the engaging portion of the rotating shaft extends through a through hole of the circuit board and is engaged in the positioning hole.

12. A mounting apparatus comprising:
a chassis comprising a positioning hole;
a mounting tray attached to the chassis; and
a securing device comprising a securing member attached to the mounting tray, a rotating shaft received in the securing member, a driving member attached to the rotating shaft, and a resilient member located between the driving member and the securing member; the rotating shaft comprises an engaging portion;
wherein the driving member rotates the rotating shaft relative to the securing member between an unlock position and a lock position; when the rotating shaft is in the unlock position, and the engaging portion is aligned with the positioning hole and is arranged in a first direction, and when the rotating shaft is in the lock position, the resilient member is deformed, and the engaging portion is engaged in the positioning hole and is arranged in a second direction substantially perpendicular to the first direction.

13. The mounting apparatus of claim 12, wherein the engaging portion comprises two first opposite ends and two second opposite ends, the positioning hole comprises two opposite long edges and two opposite short edges; when the rotating shaft is in the lock position, the two first opposite ends of the engaging portion are aligned with the two opposite short edges of the positioning hole, and when the rotating shaft is in the unlock position, the two first opposite ends of the engaging portion are aligned with the two opposite long edges of the positioning hole.

14. The mounting apparatus of claim 13, wherein a cross-section of the engaging portion is substantially a rectangle, the positioning hole is a rectangle, and a length of the engaging portion is substantially equal to a length of the positioning hole and greater than a width of the positioning hole.

15. The mounting apparatus of claim 12, wherein the securing member comprises a resisting portion, the driving member comprises an abutting portion, and the resilient member is located between the abutting portion and the resisting portion.

16. The mounting apparatus of claim 15, wherein the securing member further comprises a blocking portion, and when the rotating shaft is in the unlock position, the abutting portion abuts the blocking portion.

17. The mounting apparatus of claim 15, wherein the driving member comprises a first driving portion and a second driving portion, and the abutting portion is connected to the first driving portion and the second driving portion.

18. The mounting apparatus of claim 17, wherein the rotating shaft defines an accommodating hole, and the second driving portion is received in the accommodating hole.

19. The mounting apparatus of claim 12, wherein the securing member defines a sliding slot, the securing device further comprises an angle indicating member attached to the rotating shaft, and the angle indicating member comprises an angle indicating block slidably received in the sliding slot.

20. The mounting apparatus of claim 19, wherein the mounting tray comprises a mounting portion, the securing member defines a receiving slot, the driving member is received in the receiving slot, the mounting portion defines a clipping hole, and a clamping portion extends from an edge of the receiving slot and engaged in the clipping hole.
